(19) United States
(12) Patent Application Publication
(10) Pub. No.: US 2006/0046478 A1
(43) Pub. Date: Mar. 2, 2006

(54) Method for forming tungsten nitride film

(75) Inventor: Sung Won Lim, Gyunggi-Do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyoungki-Do (KR)

(21) Appl. No.: 11/096,407

(22) Filed: Apr. 1, 2005

(30) Foreign Application Priority Data
Aug. 31, 2004 (KR) 2004-69293
Dec. 30, 2004 (KR) 2004-117301

(51) Int. Cl. H01L 21/44; H01L 21/4763

(52) U.S. Cl. 438/681; 438/643; 438/653; 438/656; 438/648

(57) ABSTRACT

Disclosed herein is a method for forming a tungsten nitride film by introducing a tungsten precursor and a hydrazine derivative as a nitrogen source in a specific ratio into a reaction chamber, followed by deposition onto a semiconductor substrate at a given temperature by metal organic chemical vapor deposition (MOCVD) wherein the nitrogen source is a hydrazine derivative. According to the disclosed method, the use of the hydrazine derivative enables formation of a tungsten nitride film having a sufficient thickness even at low temperatures and using lesser amounts of the hydrazine derivative as compared to other nitrogen sources.

### BACKGROUND

1. Technical Field

A method for forming a tungsten nitride film by metal organic chemical vapor deposition (MOCVD) is disclosed.

2. Description of the Related Art

With the recent advance of compact, high-speed and highly integrated semiconductor devices, metal wirings using copper are used because copper has an electric resistance that is lower and electron mobility characteristics that are better than those of conventional aluminum wiring materials.

To maximize the inhibition of interlayer separation and electron mobility that may take place during the annealing of copper wiring, it is necessary to form a diffusion-preventing film using a material capable of effectively blocking the diffusion of copper and which has an excellent adhesion to copper.

Recently, tungsten nitride films along with TaN and TiN thin films have been investigated. Tungsten hexafluoride (WF₆) and ammonia (NH₃) are presently used as the primary raw materials for forming tungsten nitride films. Specifically, WF₆ and NH₃ are used as a tungsten precursor and a nitrogen source, respectively, for forming a tungsten nitride film, as depicted by Equation 1 below:
2WF₆(g)+2NH₃(g)+6H₂(g)→2WN(s)+12HF(g) Equation 1

As depicted in Equation 1, NH₃ is used as a nitrogen source to form the tungsten nitride film. Alternatively, a tungsten precursor containing a nitrogen source may be annealed to form a thin film.

Since ammonia as a nitrogen source has a high N—H bond strength of 435 KJ/mol (D. W. Robinson, J. W. Rogers Jr., Applied Surface Science 152 (1999), 85-98), it shows low dissociation efficiency. For this reason, the formation of a tungsten nitride film using ammonia has the problem that the growth temperature of the thin film needs to be high and the amount of ammonia present must be raised.

Therefore, there is an urgent need for a method for forming a tungsten nitride films by which various problems arising from the use of nitrogen sources can be solved.

### SUMMARY OF THE DISCLOSURE

Therefore, in view of the above problems, a method is disclosed for forming a tungsten nitride film by using novel materials instead of conventional nitrogen sources.

One disclosed method for forming a tungsten nitride film comprises introducing a tungsten precursor and a nitrogen source in a specific ratio into a reaction chamber, followed by deposition on a semiconductor substrate at a given temperature by metal organic chemical vapor deposition (MOCVD) wherein the nitrogen source is a hydrazine derivative.

### DESCRIPTION OF THE PRESENTLY PREFERRED EMBODIMENTS

The disclosed methods will now be described in greater detail.

A disclosed method for forming a tungsten nitride film comprises introducing a tungsten precursor and a nitrogen source in a specific ratio into a reaction chamber, followed by deposition on a semiconductor substrate at a given temperature by metal organic chemical vapor deposition (MOCVD) wherein the nitrogen source is a hydrazine derivative.

Any hydrazine derivative can be used as the nitrogen source so long as it can react with tungsten to form a tungsten nitride film. Dialkylhydrazines are preferably used. In particular, dimethylhydrazine [NH₂N(CH₃)₂] is most preferred because it is a stable liquid with a high vapor pressure (157 torr) at room temperature:

Dimethylhydrazine has a relatively low N—N bond strength of about 264 KJ/mol (D. W. Robinson, J. W. Rogers Jr., Applied Surface Science 152 (1999), 85-98), making it possible to form a tungsten nitride film even at low temperature. Accordingly, the use of dimethylhydrazine in the disclosed method enables effective formation of a tungsten nitride film. In addition, according to the disclosed method, a relatively small amount of the nitrogen source is necessary to form a tungsten nitride film having a sufficient thickness, compared to conventional deposition methods.

There is no particular restriction on the tungsten precursor used in the disclosed method and preferably, tungsten hexafluoride (WF₆) or tungsten hexacarbonyl (W(CO)₆) can be used.

In the disclosed method, the ratio of the tungsten precursor to the nitrogen source upon introduction into the reaction chamber is preferably 1:1 when the tungsten precursor is tungsten hexafluoride, and the ratio is preferably between 1:1 and 1:2 when the tungsten precursor is tungsten hexacarbonyl.

The deposition temperature for forming a tungsten nitride film is preferably in the range of 200 to 500° C., and more preferably 250 to 350° C.

In the disclosed method, the reaction between tungsten hexafluoride (WF₆) as the tungsten precursor and dimethylhydrazine [NH₂N(CH₃)₂] as the nitrogen source is represented by Equation 2 below:
2WF₆(g)+2NH₂N(CH₃)2(g)+5H₂(g)→2WN(s)+2HN(CH₃)₂(g)+12HF(g) Equation 2

In the case where tungsten hexafluoride as the tungsten precursor is used, two subsequent tungsten deposition processes along with SiH₄ and H₂ can be consecutively affected in one reaction chamber, as depicted by the following Equations 3 and 4:
2WF₆(g)+3SiH₄(CH₃)₂(g)→2W(s)+3SiF₄(g)+6H₂(g) Equation 3
WF₆(g)+3H₂(g)→W(s)+6HF(g) Equation 4

Accordingly, the disclosed method is advantageous in terms of decreased overall deposition time and improved yield of the final product.

In the disclosed method, the reaction between tungsten hexacarbonyl (W(CO)₆) as the tungsten precursor and dimethylhydrazine [NH₂N(CH₃)₂] as the nitrogen source is represented by Equation 5 below:
2W(CO)₆(g)+2NH₂N(CH₃)₂(g)+5H₂(g)→2WN(s)+2HN(CH₃)₂(g)+hydrocarbons (g) Equation 5

Advantages of the reaction are that the formation of hydrofluoric acid (HF) as a by-product during deposition is avoided and erosion of deposition equipment is prevented, thereby allowing formation of a tungsten nitride film in a stable manner.

So long as the tungsten nitride film is formed by MOCVD, the disclosed method can be applied to metal wiring processes, e.g., attachment of a tungsten plug, formation processes of a diffusion-preventing film, damascene processes, and the like, without any particular limitation, by those skilled in the art.

As apparent from the above description, according to the disclosed method, the use of a hydrazine derivative, particularly dimethylhydrazine [NH₂N(CH₃)₂], as the nitrogen source enables formation of a tungsten nitride film having a sufficient thickness even in a small amount at a relatively low temperature as compared to conventional deposition methods.

Accordingly, a semiconductor device manufactured by the disclosed method has improved reliability and yield.

In addition, in the case where tungsten hexafluoride is used as the tungsten precursor in the disclosed method, a tungsten nitride film and a tungsten film can be formed by in-situ deposition.

Furthermore, when tungsten hexacarbonyl (W(CO)₆) is used as the tungsten precursor in the disclosed method, erosion of deposition equipment arising from the formation of HF as a by-product can be prevented.

Although the preferred embodiments have been disclosed for illustrative purposes, those skilled in the art will appreciate that various modifications, additions and substitutions are possible, without departing from the scope and spirit of this disclosure and the accompanying claims.

What is claimed is:

1. A method for forming a tungsten nitride film comprising:
introducing a tungsten precursor and a hydrazine derivative as a nitrogen source into a reaction chamber,
depositing the tungsten nitride film on a semiconductor substrate in the chamber by metal organic chemical vapor deposition (MOCVD).

2. The method according to claim 1, wherein the hydrazine derivative is a dialkylhydrazine.

3. The method according to claim 2, wherein the dialkylhydrazine is dimethylhydrazine [NH₂N(CH₃)₂].

4. The method according to claim 1, wherein the tungsten precursor is tungsten hexacarbonyl (W(CO)₆).

5. The method according to claim 4, wherein the ratio of the tungsten hexacarbonyl to the nitrogen source upon introduction into the reaction chamber is between 1:1 and 1:2.

6. The method according to claim 1, wherein the tungsten precursor is tungsten hexafluoride (WF₆).

7. The method according to claim 6, wherein the ratio of the tungsten hexafluoride to the nitrogen source upon introduction into the reaction chamber is 1:1.

8. The method according to claim 1, wherein the deposition temperature for forming a tungsten nitride film is in the range of 200 to 500° C.

9. The method according to claim 8, wherein the deposition temperature is in the range of 250 to 350° C.

10. A method for forming a tungsten nitride film on a semiconductor substrate comprising:
placing the substrate in a reaction chamber,
introducing a tungsten precursor and a hydrazine into the chamber, in a ratio of at least 1:1,
carrying out a metal organic chemical vapor deposition (MOCVD) in the chamber at a temperature in the range of 200 to 500° C.

11. The method according to claim 10, wherein the hydrazine derivative is a dialkylhydrazine.

12. The method according to claim 11, wherein the dialkylhydrazine is dimethylhydrazine [NH₂N(CH₃)₂].

13. The method according to claim 10, wherein the tungsten precursor is tungsten hexacarbonyl (W(CO)₆).

14. The method according to claim 13, wherein the ratio of the tungsten hexacarbonyl to the nitrogen source upon introduction into the reaction chamber is between 1:1 and 1:2.

15. The method according to claim 10, wherein the tungsten precursor is tungsten hexafluoride (WF₆).

16. The method according to claim 10, wherein the deposition temperature is in the range of 250 to 350° C.
